(19) United States
(12) Patent Application Publication
(10) Pub. No.: US 2017/0038506 A1
(43) Pub. Date: Feb. 9, 2017

(54) Color Filter Substrate and Manufacturing for the Same

(71) Applicant: Shenzhen China Star Optoelectronics Technology Co. Ltd., Shenzhen, Guangdong (CN)

(72) Inventor: Jiangjiang SONG, Shenzhen, Guangdong (CN)

(73) Assignee: Shenzhen China Star Optoelectronics Technology Co. Ltd., Shenzhen, Guangdong (CN)

(21) Appl. No.: 14/777,842

(22) PCT Filed: Aug. 12, 2015
(86) PCT No.: PCT/CN2015/086782

§ 371 Date: Sep. 17, 2015

(30) Foreign Application Priority Data
Aug. 6, 2015 (CN) 20151047721.6

(51) Int. Cl. G02B 5/20; G03F 7/00; G03F 7/40; G03F 7/32; G03F 7/16; G02F 1/1335; G03F 7/20

(52) U.S. Cl. CPC G02B 5/201; G02F 1/133516; G02F 1/133512; G03F 7/0007; G03F 7/20; G03F 7/32; G03F 7/168; G03F 7/40

(57) ABSTRACT

The present invention proposes a color filter substrate and a method for manufacturing the same. The method includes: (S101) providing a glass substrate and a photo-sensitive black material layer on the glass substrate; (S102) exposing the photo-sensitive black material layer via an exposure mask; (S103) imposing a first development process on the photo-sensitive black material layer to derive an initial black matrix on the glass substrate; and (S104) imposing a second development process on the initial black matrix to derive a completed black matrix on the glass substrate.

### BACKGROUND OF THE INVENTION

1. Field of the Invention

The present invention relates to liquid crystal display technology field, more particularly to a color filter substrate and manufacturing for the same.

2. Description of the Prior Art

A liquid crystal display (LCD) has such merits of thinness, lightness, power saving, and low radiation as to be applied in notebook computers, mobile phones, electronic dictionaries and other electronic display devices. As per the LCD technology having been developing, so changes the environment in which the electronic display devices are used. They are more often used outdoors. Demand on visual effects is rising, so a LCD device of greater lightness is expected. The LCD panel is a main component of the LCD.

A liquid crystal display panel comprises a thin film transistor (TFT) array substrate, a color filter substrate, and a liquid crystal layer. A color filter substrate filters white light into different colors of light, which then reunite as image results. A color filter substrate comprises a glass substrate and a black matrix as well as a color photoresist built via etch process with masks. As display resolution has been demanded to be higher and higher these years, pixels per inch must increase, while the black matrix needs to be in thinner line width, in order to increase aperture ratio, especially in small-size liquid crystal display panels.

Please refer to FIG. 1. A conventional method for manufacturing color filter substrates comprises the following steps:

S1. Provide a glass substrate 1 and build on the same a photo-sensitive black material layer 2, as shown in FIG. 1 (a). Then pre-bake the photo-sensitive black material layer 2.

S2. Expose the photo-sensitive black material layer 2 via an exposure mask 3, in order to solidate the exposed area, as shown in FIG. 1 (b).

S3. Remove the unexposed area of the photo-sensitive black material layer 2 via development process while keeping the exposed and solidated area intact, so as to form a black matrix 4 on the glass substrate 1, as shown in FIG. 1 (c). Then post-bake the black matrix 4.

S5. Build a color photoresist 5 on the glass substrate 1, on which the black matrix 4 has been formed, as shown in FIG. 1 (d). The color photoresist 5 comprises a red photoresist 5R, a green photoresist 5G, and a blue photoresist 5B.

In the above manufacturing steps of color filter substrates, during the process of forming the black matrix 4 by exposing and developing the photo-sensitive black material layer 2, the upper end of the photo-sensitive black material layer 2 develops faster than the lower end. Therefore, as shown in FIG. 2, the black matrix 4 formed has a narrower top surface 41 and a wider bottom surface 42. The top surface 41 is connected to the bottom surface 42 with a slope 43. The angle between the bottom surface 42 and the slope 43 is a taper angle α, with α being 20 to 40 degrees in conventional manufacturing method. If the width of the top surface 41 is set to be constant, then a smaller α makes a larger width of the bottom surface 42, meaning a larger width of the black matrix 4 as a whole, resulting in aperture ratio loss. Since the width of the top surface 41 cannot be unlimitedly reduced, a larger a shortens the width of the bottom surface 42, so as to reduce the width of the black matrix 4 as a whole, and thus increases aperture ratio of liquid crystal display panels.

### SUMMARY OF THE INVENTION

In view of the weakness of conventional technology, the present invention provides a color filter substrate and manufacturing for the same, which improves the exposure and development process of formation of the black matrix. By increasing the angle between the bottom and the slope of the black matrix, the line width of the black matrix as a whole will be decreased, and aperture ratio of liquid crystal display panels will be increased.

According the present invention, a method for manufacturing a color filter substrate comprises: (S101) providing a glass substrate and a photo-sensitive black material layer on the glass substrate; (S102) exposing the photo-sensitive black material layer via an exposure mask; (S103) imposing a first development process on the photo-sensitive black material layer to derive an initial black matrix on the glass substrate; and (S104) imposing a second development process on the initial black matrix to derive a completed black matrix on the glass substrate.

Furthermore, a width of a top surface of the completed black matrix is narrower than a width of the bottom surface of the completed black matrix, the top surface is connected to the bottom surface with a slope, and an angle β between the bottom surface and the slope 403 is in a range of 40 to 60 degrees.

Furthermore, a width of a top surface of the completed black matrix is 3˜4 μm and a width of a bottom surface of the completed black matrix is 6μ7 μm.

Furthermore, a step S101 further comprises pre-baking the photo-sensitive black material layer, at 80 to 110 degrees Celsius, for 80 to 120 seconds.

Furthermore, a step S103 further comprises post-baking the initial black matrix for a first time, at 200 to 250 degrees Celsius, for 5 to 30 minutes.

Furthermore, a step S104 further comprises post-baking the completed black matrix for a second time, at 200 to 250 degrees Celsius, for 5 to 30 minutes.

Furthermore, a thickness of the black matrix is 1˜2.5 μm.

Furthermore, the method further comprises: forming the color photoresist within a plurality of openings surrounded by the completed black matrix.

Furthermore, the color photoresist comprises a red photoresist, a green photoresist, and a blue photoresist.

According to the present invention, a color filter substrate is manufactured by using the above method.

In contrast to prior art, manufacturing for a color filter substrate of the present invention implements exposure and development process for two times in a row on the photo-sensitive black material layer to form the black matrix, so as to increase the angle between the bottom and the slope of the black matrix while keeping the width of the top surface of the black matrix unchanged, namely to reduce the width of the bottom surface of the black matrix as a whole, and thus aperture ratio of liquid crystal display panels can be increased.

### BRIEF DESCRIPTION OF THE DRAWINGS

FIG. 1 shows a flowchart of a conventional method for manufacturing color filter substrates.

FIG. 2 shows a black matrix formed by using a conventional method.

FIG. 3 shows a flowchart of a method of manufacturing color filter substrates according to a preferred embodiment of the present invention.

FIG. 4 shows a flowchart of a method of manufacturing a red color resist according to a preferred embodiment of the present invention.

FIG. 5 shows a black matrix formed by using the present invention.

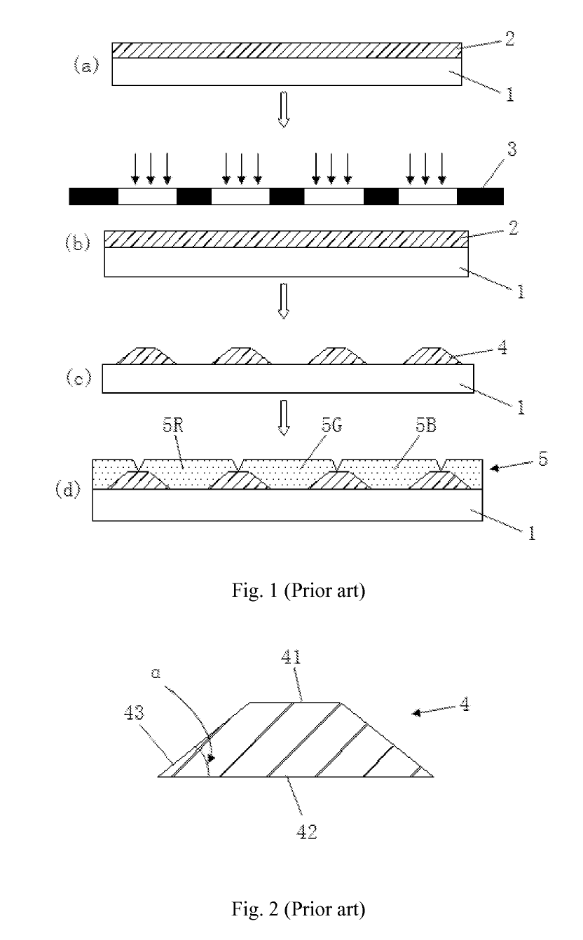

### DETAILED DESCRIPTION OF THE PREFERRED EMBODIMENTS

For better understanding embodiments of the present invention, the following detailed description taken in conjunction with the accompanying drawings is provided. Apparently, the accompanying drawings are merely for some of the embodiments of the present invention. Any ordinarily skilled person in the technical field of the present invention could still obtain other accompanying drawings without use laborious invention based on the present accompanying drawings.

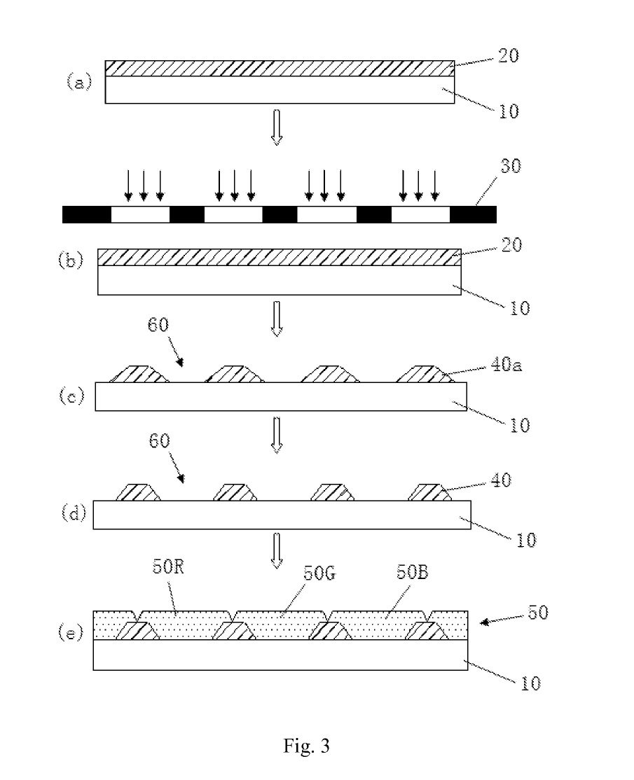

Please refer to FIG. 3 showing a flowchart of a method of manufacturing for a color filter substrate according to the preferred embodiment of the present invention. The method comprises the flowing steps:

S101. Provide a glass substrate 10 and a photo-sensitive black material layer 20 thereon, as shown in FIG. 3 (a). More particularly, wash the glass substrate 10. Deionized water may be used in the wash. If the glass substrate 10 has oil spots, then surfactant detergent can be used. Second, form the photo-sensitive black material layer 20, with thickness of 1 to 2.5 μm, on the washed glass substrate 10. Furthermore, pre-bake the photo-sensitive black material layer 20, at 80 to 110 degrees Celsius, for 80 to 120 seconds.

S102. Expose the photo-sensitive black material layer 20 via an exposure mask 30, in order to solidate the exposed area, as shown in FIG. 3 (b). Preferably, the photo-sensitive black material is electronegative.

S103. Impose a first development process on the photo-sensitive black material layer 20, in order to derive an initial black matrix 40a, with a plurality of openings 60, as shown in FIG. 3 (c). More particularly, first, develop the photo-sensitive black material layer 20 for about 80 seconds by using a developer which KOH is preferred. In the process, the unexposed area of the photo-sensitive black material layer 20 will dissolve in the developer, while the exposed and solidated area remain intact, forming the initial black matrix 40a in the end. Then, post-bake the initial black matrix 40a for a first time, at 200 to 250 degrees Celsius, for 5 to 30 minutes. For example, if the temperature is set at 230 degrees Celsius, then the time should be set for 10 minutes.

S104. Impose a second development process on the initial black matrix 40a, in order to derive a completed black matrix 40 on the glass substrate 10, as shown in FIG. 3 (d). The same developer as in S103 should be used. After the second development process, the width of the initial black matrix 40a is narrowed down. Namely, the completed black matrix 40 has a narrower bottom width than that of the initial black matrix 40a. Then, post-bake the completed black matrix 40 for a second time, at 200 to 250 degrees Celsius, for 5 to 30 minutes. For example, if the temperature is set at 230 degrees Celsius, then the time should be set for 10 minutes.

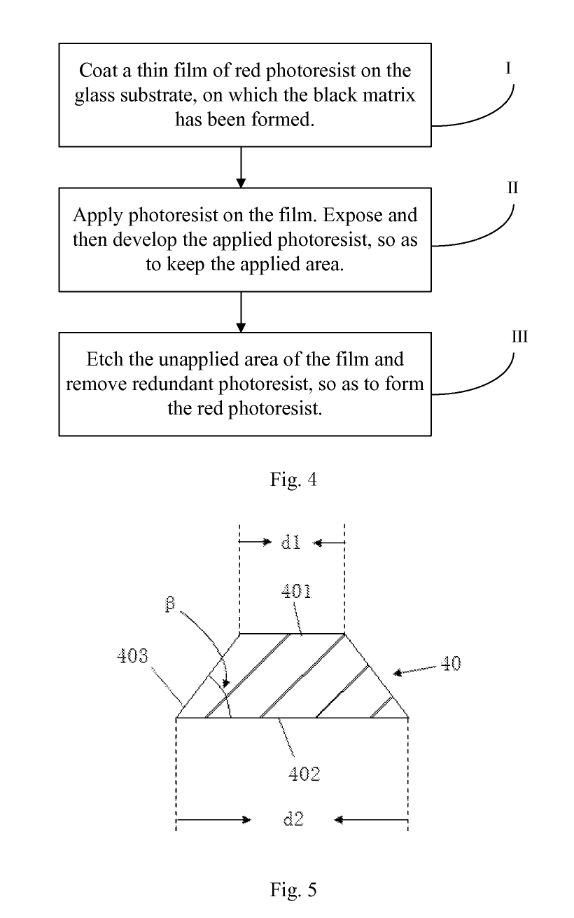

S105. Build a color photoresist 50 on the glass substrate 10, on which the black matrix 40 has been formed, as shown in FIG. 3 (e). The color photoresist 50 comprises a red photoresist 50R, a green photoresist 50G, and a blue photoresist 50B. More particularly, please refer to FIG. 4 showing a preferred embodiment of manufacturing the red photoresist 50R, comprising the following steps.

I. Coat a thin film of red photoresist on the glass substrate 10, on which the black matrix 40 has been formed.

II. Apply photoresist on the film. Expose and then develop the applied photoresist, so as to keep the applied area.

III. Etch the unapplied area of the film and remove redundant photoresist, so as to form the red photoresist 50R.

Repeat Steps I to III to further form the green photoresist 50G and the blue photoresist 50B respectively. Each of the color resists (the red photoresist 50R, the green photoresist 50G, and the blue photoresist 50B) is form in one of the openings 60 among the black matrix 40.

Please refer to FIG. 5. The completed black matrix 40 has a narrower top surface 401 of width d1 and a wider bottom surface 402 of width d2. The top surface 401 is connected to the bottom surface 402 with a slope 403. The angle between the bottom surface 402 and the slope 403 is β. β is in the range of 40 to 60 degrees. The width d1 is in the range of 3 to 4 μm. The width d2 is in the range of 6 to 7 μm.

In contrast to prior art, manufacturing for a color filter substrate of the present invention implements exposure and development process for two times in a row on the photo-sensitive black material layer to form the black matrix, so as to increase the angle between the bottom and the slope of the black matrix while keeping the width of the top surface of the black matrix unchanged, namely to reduce the width of the black matrix as a whole, and thus aperture ratio of liquid crystal display panels can be increased.

The terms “a” or “an”, as used herein, are defined as one or more than one. The term “another”, as used herein, is defined as at least a second or more. The terms “including” and/or “having” as used herein, are defined as comprising. It should be noted that if it is described in the specification that one component is “connected,” “coupled” or “joined” to another component, a third component may be “connected,” “coupled,” and “joined” between the first and second components, although the first component may be directly connected, coupled or joined to the second component.

While the present invention has been described in connection with what is considered the most practical and preferred embodiments, it is understood that this invention is not limited to the disclosed embodiments but is intended to cover various arrangements made without departing from the scope of the broadest interpretation of the appended claims.

What is claimed is:

1. A method for manufacturing a color filter substrate, comprising:
(S101) providing a glass substrate and a photo-sensitive black material layer on the glass substrate;
(S102) exposing the photo-sensitive black material layer via an exposure mask;
(S103) imposing a first development process on the photo-sensitive black material layer to derive an initial black matrix on the glass substrate; and
(S104) imposing a second development process on the initial black matrix to derive a completed black matrix on the glass substrate.

2. The method of claim 1, wherein a width of a top surface of the completed black matrix is narrower than a width of the bottom surface of the completed black matrix, the top surface is connected to the bottom surface with a slope, and an angle β between the bottom surface and the slope 403 is in a range of 40 to 60 degrees.

3. The method of claim 1, wherein a width of a top surface of the completed black matrix is 3˜4 μm and a width of a bottom surface of the completed black matrix is 6˜7 μm.

4. The method of claim 1, wherein a step S101 further comprises pre-baking the photo-sensitive black material layer, at 80 to 110 degrees Celsius, for 80 to 120 seconds.

5. The method of claim 1, wherein a step S103 further comprises post-baking the initial black matrix for a first time, at 200 to 250 degrees Celsius, for 5 to 30 minutes.

6. The method of claim 1, wherein a step S104 further comprises post-baking the completed black matrix for a second time, at 200 to 250 degrees Celsius, for 5 to 30 minutes.

7. The method of claim 1, wherein a thickness of the black matrix is 1˜2.5 μm.

8. The method of claim 1 further comprising: forming the color photoresist within a plurality of openings surrounded by the completed black matrix.

9. The method of claim 8, wherein the color photoresist comprises a red photoresist, a green photoresist, and a blue photoresist.

10. A color filter substrate comprising a black matrix and a plurality of color photoresists on a glass substrate, the plurality of color photoresists formed within a plurality of openings surrounded by the black matrix, wherein steps for forming the black matrix comprises:
(S101) providing a glass substrate and a photo-sensitive black material layer on the glass substrate;
(S102) exposing the photo-sensitive black material layer via an exposure mask;
(S103) imposing a first development process on the photo-sensitive black material layer to derive an initial black matrix on the glass substrate; and
(S104) imposing a second development process on the initial black matrix to derive a completed black matrix on the glass substrate.

11. The color filter substrate of claim 10, wherein a width of a top surface of the completed black matrix is narrower than a width of the bottom surface of the completed black matrix, the top surface is connected to the bottom surface with a slope, and an angle β between the bottom surface and the slope 403 is in a range of 40 to 60 degrees.

12. The color filter substrate of claim 10, wherein a width of a top surface of the completed black matrix is 3˜4 μm and a width of a bottom surface of the completed black matrix is 6˜7 μm.

13. The color filter substrate of claim 10, wherein the step S101 further comprises pre-baking the photo-sensitive black material layer, at 80 to 110 degrees Celsius, for 80 to 120 seconds.

14. The color filter substrate of claim 10, wherein a step S103 further comprises post-baking the initial black matrix for a first time, at 200 to 250 degrees Celsius, for 5 to 30 minutes.

15. The color filter substrate of claim 10, wherein a step S104 further comprises post-baking the completed black matrix for a second time, at 200 to 250 degrees Celsius, for 5 to 30 minutes.

16. The color filter substrate of claim 10, wherein a thickness of the black matrix is 1˜2.5 μm.

17. The color filter substrate of claim 10, wherein the color photoresist comprises a red photoresist, a green photoresist, and a blue photoresist.
